(19) United States
(12) Patent Application Publication
(10) Pub. No.: US 2013/0340823 A1
(43) Pub. Date: Dec. 26, 2013

(54) SELECTIVE AND/OR FASTER REMOVAL OF A COATING FROM AN UNDERLYING LAYER, AND SOLAR CELL APPLICATIONS THEREOF

(71) Applicant: TETRASUN, INC, San Jose, CA (US)

(72) Inventors: Qing Yuan ONG, San Leandro, CA (US); Adrian Bruce TURNER, Palo Alto, CA (US)

(21) Appl. No.: 13/914,213

(22) Filed: Jun. 10, 2013

Related U.S. Application Data
(60) Provisional application No. 61/657,098, filed on Jun. 8, 2012.

(51) Int. Cl. H01L 31/18; H01L 31/0216

(52) U.S. Cl. CPC H01L 31/18; H01L 31/02167
USPC 136/256; 438/71

(57) ABSTRACT

A method for patterning a film pattern on a substrate includes forming a film pattern on a substrate surface, forming a coating over the substrate and the film pattern and inducing porosity or openings in the coating. At least a part of the coating overlying the film pattern is removed including etching at least one layer underlying the coating ahead of removing at least part of the coating.

### CROSS-REFERENCE TO RELATED APPLICATIONS

This application claims priority to U.S. Provisional application No. 61/657,098, filed on Jun. 8, 2012, the entire disclosure of which is incorporated herein by reference.

This Application is also related to the commonly-assigned, previously filed U.S. Provisional Application entitled “High-Efficiency Solar Cell Structures and Methods of Manufacture,” filed Apr. 21, 2009, and assigned U.S. Provisional Application Ser. No. 61/171,194; and to commonly-assigned, International Patent Application entitled “High-Efficiency Solar Cell Structures and Methods of Manufacture” filed on Apr. 21, 2009, and assigned PCT Application Serial Number PCT/US10/31869. Each of these Applications is hereby incorporated by reference herein in its entirety. All aspects of the present invention may be used in combination with any of the disclosures of the above-noted Applications.

This Application is also related to the commonly-assigned, previously filed U.S. Provisional Application entitled “Selective Removal Of A Coating From A Metal Layer, And Solar Cell Applications Thereof,” filed Jan. 23, 2012, and assigned U.S. Provisional Application Ser. No. 61/589,459. These applications are hereby incorporated by reference herein in their entirety. All aspects of the present invention may be used in combination with any of the disclosures of the above-noted Application.

### TECHNICAL FIELD

The present invention relates to solar cells and modules. More particularly, the present invention relates to improved solar cell structures and methods of manufacture for increased cell efficiency.

### BACKGROUND

Solar cells are providing widespread benefits to society by converting essentially unlimited amounts of solar energy into useable electrical power. As their use increases, certain economic factors become important, such as high-volume manufacturing and efficiency.

With reference to the schematic views of exemplary solar cells of FIGS. 1-3, solar radiation is assumed to preferentially illuminate one surface of a solar cell, usually referred to as the front side. In order to achieve a high energy conversion efficiency of incident photons into electric energy, an efficient absorption of photons within a silicon wafer is important. This may be achieved by a good surface texturing and an antireflection coating on the front side, along with a low parasitic absorption within all layers except the wafer itself. An important parameter for high solar cell efficiency is an amount of shading of the front surface by metal electrodes. In general, an optimized metal grid is a tradeoff of losses between the shading and an electrical resistance of the metal structure of the grid. The optimization for efficiency of the solar cell includes a grid with very fine fingers and short distances in between those fingers, which should have a high electrical conductivity.

Standard solar cell production technology uses screen printing technology to print an electrode on a front surface of the cell. A silver paste is printed on top of a silicon nitride antireflection coating and fired through the coating in a high temperature process. This is a short process sequence and has therefore gained the highest market share in crystalline silicon solar cell technology. However, certain inherent properties of this approach include a comparatively broad line width in excess of 50 μm (typically about 100 um) and a fairly low line conductivity of the metal grid due to the use of several non-metallic components in the printed paste. Also, the firing process results in a penetration of the metal paste ingredients through the antireflection layer into the substrate where increased recombination occurs. This holds for both cases of a front junction device where a pn-junction can be severely damaged by unwanted penetration of the space charge region as well for back junction devices where the front surface recombination is increased and significantly reduces the collection efficiency of the back junction emitter.

Thus, a need exists for improved systems and methods for manufacturing solar cells.

### SUMMARY OF THE INVENTION

The present invention provides, in one aspect, a method for patterning a film pattern on a substrate which includes forming a film pattern on a substrate surface, forming a coating over the substrate and the film pattern and inducing porosity or openings in the coating. At least a part of the coating overlying the film pattern is removed including etching at least one layer underlying the coating ahead of removing at least part of the coating.

### BRIEF DESCRIPTION OF THE DRAWINGS

FIG. 1 is a side cross-sectional view of a portion of a solar cell having a metal pattern and a coating on a substrate in accordance with the present invention;

FIG. 2 is a side cross-sectional view of the solar cell of FIG. 1 with the metal pattern plated;

FIG. 3 is a side cross-sectional view of the solar cell of FIG. 1 with layers of the metal pattern depicted;

FIG. 4 is a side cross-sectional view of a portion of a solar cell including a metal film and a substrate;

FIG. 5 is a side cross-sectional view of the solar cell of FIG. 4 including a resist;

FIG. 6 is a side cross-sectional view of FIG. 5 after etching thereof;

FIG. 7A is a side cross-sectional view of the solar cell of FIG. 6 after further etching;

FIG. 7B is a side cross-sectional of the solar cell of FIG. 6 after further etching;

FIG. 8 is a side cross-sectional view of the solar cell of FIG. 6 after a resist is removed;

FIG. 9 is a side cross-sectional view of a portion of the solar cell having a dielectric coating over a substrate and a metal contact;

FIG. 10A is a side cross-sectional of the solar cell of FIG. 9 after etching thereof;

FIG. 10B is an additional side cross-sectional of the solar cell of FIG. 9 after etching thereof;

FIG. 11 is a sides cross-sectional view of the solar cell of FIG. 10B after the remaining portion of the coating thereof is removed;

FIG. 12 is a side cross-sectional view of the solar cell of FIG. 11 after plating of the metal film;

FIG. 13 is a front elevational view of a metal pattern and a metal contact including bus bars and line fingers;

FIG. 14A is a close up of the metal fingers of FIG. 13;

FIG. 14B depicts the metal fingers of FIG. 14A after metal etching and dielectric coating removal;

FIG. 15 is a table listing etchants for selective removal of materials;

FIG. 16 depicts materials that may be utilized for etching;

FIG. 17 is a side cross-sectional view of a portion of a solar cell including a metal contact and dielectric coating;

FIG. 18 is a side-cross sectional view of the solar cell of FIG. 17 with the metal contact plated;

FIG. 19 is a side cross-sectional view of a metal contact deposited on a substrate;

FIG. 20 is a side cross-sectional view of the substrate and metal film having a resist line thereon;

FIG. 21A is a side cross-sectional view of the substrate and contact of FIG. 20 with an undercut;

FIG. 21B is an additional side cross-sectional view of the substrate and contact of FIG. 20 with an undercut;

FIG. 22 is a side cross-sectional view of the substrate on the film and resist of FIG. 20 with the resist removed;

FIG. 23 is a side cross-sectional view of the substrate and film of FIG. 22 with a coating applied thereof;

FIGS. 24A-24B are side cross-sectionals view depicting laser irradiation of the substrate film and coating of FIG. 23;

FIG. 25 depicts a portion of the coating of FIG. 24 removed;

FIG. 26 depicts the substrate from the coating of FIG. 25 with the metal film plated;

FIG. 27 depicts an elevational view of a metal pattern including bus bars and narrow lined fingers;

FIG. 28A depicts a close-up of a portion of FIG. 27;

FIG. 28B depicts the metal pattern of FIG. 28A after laser beam irradiation.

FIG. 29 is a block diagram of a laser machining system;

FIG. 30 depicts two laser beam profiles;

FIG. 31A depicts a square spot of laser irradiation that may be scanned or translated;

FIG. 31B depicts a selective laser ablation process;

FIG. 32A depicts a square top-head profile laser beam spot process; and

FIG. 32B depicts a selective laser ablation process.

### DETAILED DESCRIPTION

Aspects of the present invention and certain features, advantages, and details thereof; are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions, and/or arrangements within the spirit and/or scope of the underlying inventive concepts will be apparent to those skilled in the art from this disclosure.

In accordance with the principles of the present invention, systems and methods manufacturing solar cells are provided.

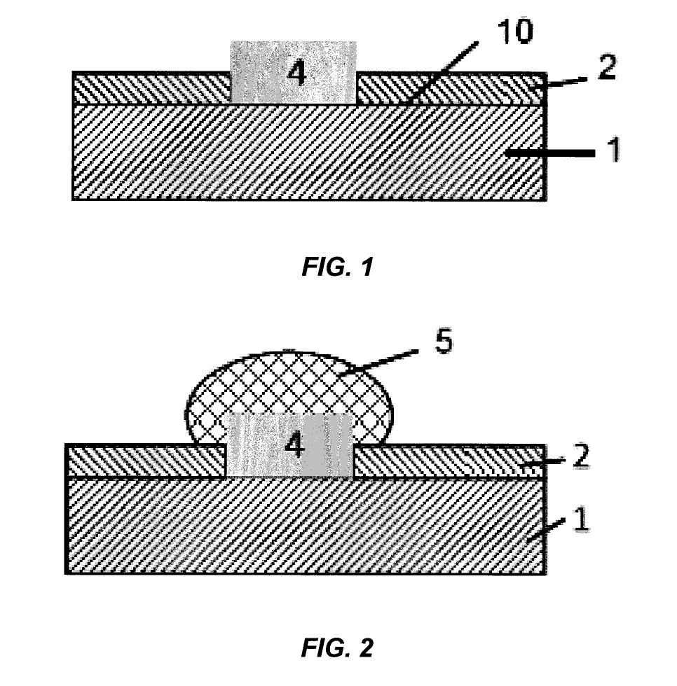

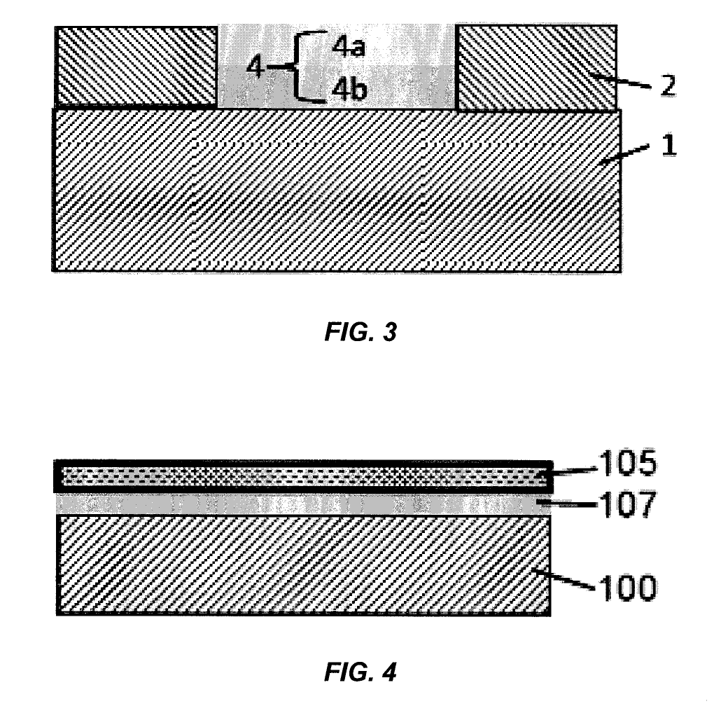

In an exemplary embodiment, An improved structure for the front side metallization is depicted in FIG. 1. A contact 4 may have a line width on the order of 50 μm or less and the total surface coverage with metal of the front side may be about 7% or less.

Thin metal contact 4 may subsequently be plated to result in a plated metal contacts at a required thickness in order to obtain a higher conductivity. Using electroplating for the buildup of the line conductivity, a sufficient thickness of the metal contact 4 on the order of ˜50-500 nm is required in order to enable good plated metal uniformity of plated metal contact 4. It is understood that when plating is performed an antireflection coating 2 may also function as a plating barrier to prevent metal plating onto a surface 10 of a substrate 1, for this reason alone the antireflection coating must be a good electrical insulator e.g. a largely intact dielectric film). Metal contact 4 may be made up of multiple layers. As an example, contact 4 is shown as including two layers i.e., top first layer 4a and second layer 4b in FIG. 3.

The present invention includes, in one aspect, a method for manufacturing conductive metal grids on substrates (e.g., solar cells) which enhances the selectivity and/or speed in removing some or all of top layer(s) on such substrates, by etching some or all of the underlying layer(s) which may be patterned beforehand.

In one possible invention embodiment of enhancing the removal speed, a resist is used to locally mask a stack comprising several layers (e.g., 4a, 4b, etc.). If the resist loses masking effectiveness when exposed for longer times to a particular etchant, such as one used for top layer 4a, it is helpful to etch top layer 4a faster. This may be achieved by having an etchant go through top layer 4a via pinholes or other openings that are already present or introduced prior to this step to etch the underlying layers, (e.g., 4b). This allows top layer 4a to be etched by its etchant on both sides because of an increased surface area being exposed, resulting in a faster overall etch rate and shorter etch times. This ensures the resist can mask effectively during the local etch back of the layer(s). The resist is then removed and followed by the deposition of a dielectric coating on the full area including the patterned area, which may be metalized.

In another possible invention embodiment of enhancing selective removal, a dielectric coating is removed from on top of the metal (e.g., contact 4) by etching some or all of the underlying metal layers (e.g., top layer 4a, second layer 4b), again by having the etchant go through pinholes or openings present in the dielectric coating.

In a further possible invention embodiment of enhancing selective removal, inkjet or aerosol printing of metal nanoparticles is used to form a metal pattern, followed by the deposition of a dielectric coating on the full area including the metalized area, and the selective removal of the dielectric coating from on top of the metal by etching some or all of the underlying metal layers.

In a further possible invention embodiment of enhancing selective removal, screen printing of metal paste is used to form a metal pattern, followed by the deposition of a dielectric coating on the full area including the metalized area, and the selective removal of the dielectric coating from on top of the metal by etching some or all of the underlying metal layers.

The present invention offers many distinct advantages over current state of the art. Specifically, it is a simple technique for the formation a metal pattern (e.g., metal contact 4) surrounded by a dielectric coating (e.g., coating 2) for solar cells, where the dielectric coating may function as an antireflection coating on the front surface, internal reflector on the rear surface and may further may function as a dielectric barrier for subsequent electroplating of metal patterns on either surface. Also, this is a favorable way of fabricating interdigitated contact grids for contact structures that are made on one side of the substrate only.

In one embodiment of this invention very fine metal patterns may be generated as the dielectric coating is selectively removed by etching only from those substrate areas covered with patterned metal even though the entire substrate is immersed in or coated with the etchant. This selective removal of a dielectric coating (e.g., coating 2) is a self-aligned patterning processes as it relies on the removal of the underlying metal (e.g., contact 4) supporting the dielectric coating. The dielectric coating and substrate in those areas not covered by metal is largely unaffected by the etching, even though these areas are also exposed to the same etchant. This self-aligned removal of the dielectric coating means that very narrow metal patterns (e.g., FIG. 1) may be generated, the size of the dielectric coating opening only being governed by the metal pattern size and the type of etchant. Furthermore, such a self-aligned selective etching patterning is a simple, high yield and cost effective manufacturing process.

The selective removal and patterning of the dielectric coating avoids any gap between the metal and the dielectric antireflection coating as otherwise can be observed in techniques such as metal lift off This is important because the dielectric coating acts as a barrier between the substrate and any plated metal and the surrounding environment.

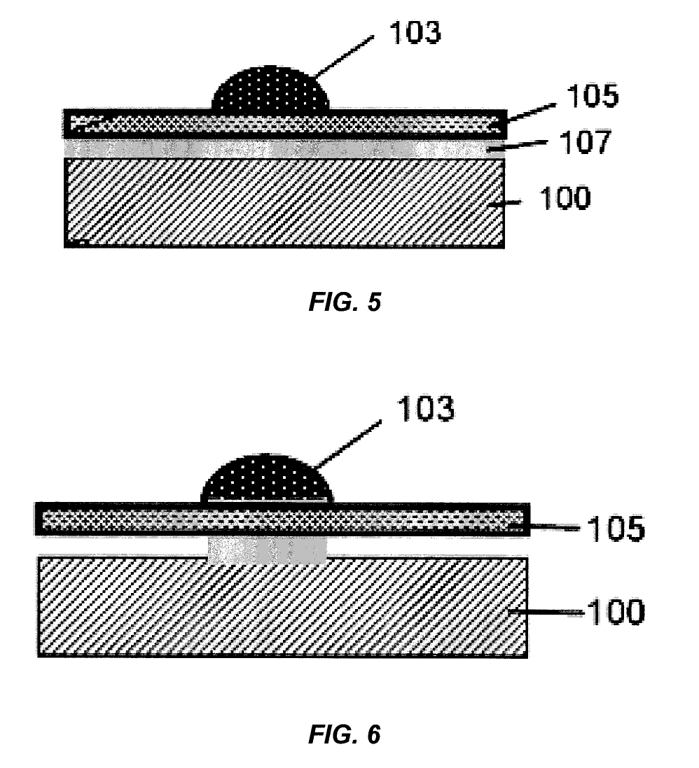

FIGS. 4-11 depict an example embodiment of the invention which uses a metal etch resist to form a metal grid pattern for a solar cell. It is understood that many techniques exist for the formation of a metal patterns on a substrate in accordance with the present invention and that the sequence presented is only one possible example.

A substrate 100 is supplied. This substrate may be a silicon semiconductor wafer of either p or n-type doping. The substrate may be textured, for example with a random pyramid pattern to improve light trapping in the solar cell. The substrate may have dopant diffusions on either or both sides to form emitter structures or surface fields. Such dopant diffusions may be patterned, for example to form so called selective emitter structures. The substrate may have thin film passivation layers present on either or both surfaces. Such passivation layers may for example consist of doped or intrinsic amorphous silicon layers, silicon dioxide, silicon nitride, doped or intrinsic poly-silicon, doped or intrinsic silicon carbide, aluminum oxide or any of a large variety of such passivation layers and combinations thereof.

A metal film 104 including layers 105 and 107, is e.g., deposited onto a surface of the substrate, and the structure shown in FIG. 4 results. Such metal deposition may, for example, be performed using well established techniques such as sputtering, thermal evaporation or e-beam evaporation. It is understood that this metal film may consist of multiple different metal layers where these metal layers are required to perform different functions. For example, a bottom (next to the substrate) metal layer maybe required to form good electrical contact and adhesion to the substrate, a top or middle metal layer may be required to act as a diffusion barrier and a top metal layer may need to function as an electroplating seed. Further, it is understood that the metal film may require specific properties, for example thickness and/or composition, to enable the subsequent selective dielectric laser ablation.

A narrow resist 103 is e.g., dispensed on top of metal film104, and the structure shown in FIG. 5 results. Resist 103 may form any pattern on the surface of the substrate. In the case of a solar cell such a pattern may, for example, include many narrow fingers and several wider bus-bars. Resist 103 may be dispensed, for example, by inkjet or screen printing. Alternatively, resist 103 could be formed by photolithography.

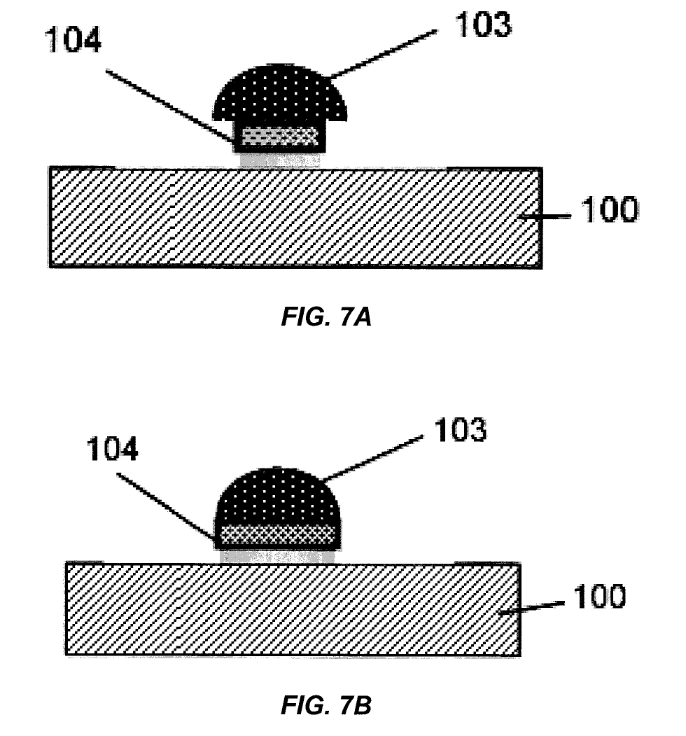

Metal film 4 may be patterned, (e.g., etched except for the parts covered by resist 3 and may, for example, be performed by acid etching. The degree of metal etching may be controlled to create a large or small or no undercut thus defining a final line width. A first etching step removes underlying layer 107, leaving top layer 105 exposed on both sides for faster etching as shown in FIG. 6. A second etching step may be performed to remove top layer 105, resulting in the structure shown in FIG. 7A showing a large metal undercut on the structure depicted in FIG. 7B showing a small or nonexistent metal undercut, either of which define a final line width.

The resist may be removed and a metal pattern (e.g., narrow metal line) left on the substrate, and the structure shown in FIG. 8 results. In the case of the front surface of solar cell, finger widths of e.g. less than 50 μm may readily be achieved.

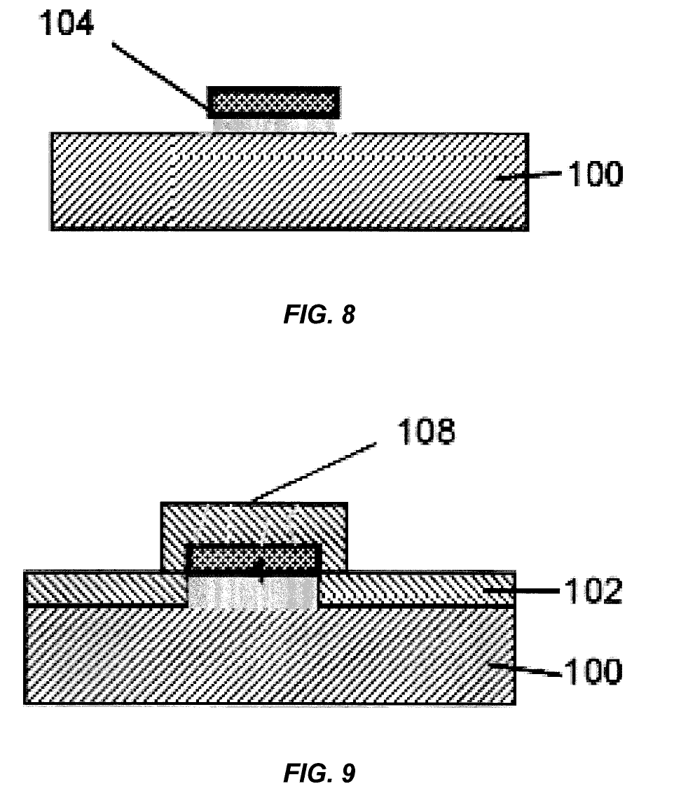

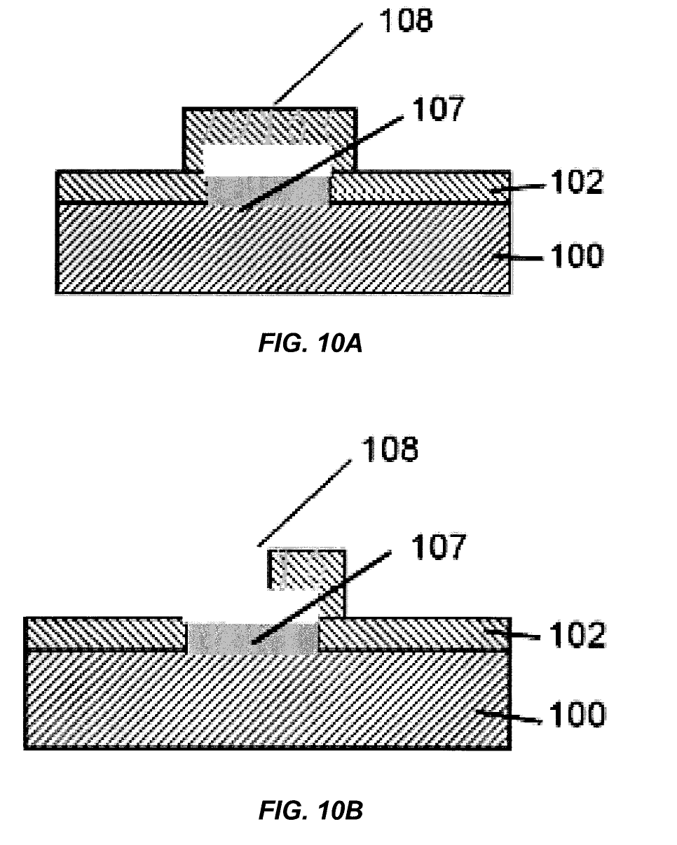

A dielectric coating 102 may be deposited across the entire surface (e.g., of substrate 100 and contact 104, for example, and the structure shown in FIG. 9 results. Such dielectric deposition may, for example, be performed using well established techniques such as sputtering, dip coating, chemical vapor deposition and plasma enhanced chemical vapor deposition. In the case of the front surface of a solar cell it is understood that this dielectric coating (e.g., coating 2) may function as an antireflection coating and may also passivate the surface of the solar cell. Further, it is understood that this dielectric layer may be composed of multiple different layers and/or graded layers, to for example implement well known techniques to improve antireflection properties. Since the etchant will need to go through pinholes or openings in the top layer, it may be necessary to introduce these pinholes and openings prior the next step. This may be achieved using methods that may be chemical (such as etch, targeted bonding etc.), physical (such as laser ablation, physical impingement, ultrasonic, plasma etch etc.), electrical (such as electrical field assisted processes), topographical (such as film quality change due to underlying texture and dimensions) etc. The method is preferably selective to the underlying pattern. A portion 108 of dielectric coating 2 overlays metal contact 104.

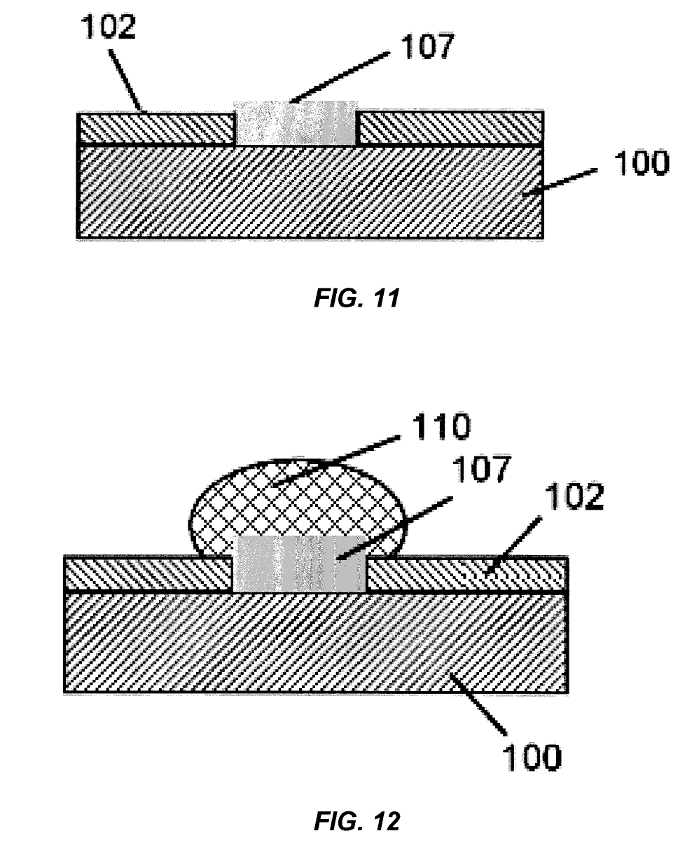

In one embodiment, the entire substrate (e.g., substrate 100 with contact 104 and coating 102) may then be immersed in an etching solution to selectively remove top metal layer 105 underlying dielectric coating 102, as shown in FIG. 10A. Alternatively, the etchant selection and application method may be chosen such that the etchant may interact with the dielectric coating or other metal layers, or the etchant may be applied selectively to those areas which have the metal pattern to remove the underlying layer(s). The removal of the underlying layers may also be partial. This etching step may also liftoff some or all or none of portion 108 of dielectric coating 102 as depicted in FIG. 10B. The remaining portion of coating 102 (i.e., that is not removed) may be left unsupported over a gap (FIG. 10B) and may be easily removed by other methods such as ultrasonic cleaning, physical impingement (water, dry ice, pressured air etc.) to result in the structure shown in FIG. 11.

Subsequent processes may be performed on the substrate, for example cleaning to remove debris or thermal treatment to improve electrical contact. In the case of the front surface of a silicon solar cell metal film 104 may be thickened by plating to result in thickened metal contact 110, as shown in FIG. 12, to achieve a required line conductivity.

The above described example illustrates an inventive process sequence for the formation of metal contact structures for solar cells. The process sequence may include:
1) Deposit metal film on substrate;
2) Dispense resist;
3) Etch metal (can be underlying first) and remove resist;
4) Deposit dielectric film and if necessary, followed by method to induce porosity or openings in top coating preferably selective to underlying pattern;
5) Underlying metal etching and dielectric coating removal; and
6) Plate

In another example, an inventive process sequence for the formation of metal contact structures for solar cells may include:
1) Deposit metal film on substrate;
2) Dispense resist;
3) Etch metal (including possibly removing underlying layer first);
4) Remove resist;
5) Deposit dielectric film (e.g., nitride);
6) Use laser ablation (using, e.g., the techniques of the above incorporated U.S. Provisional Patent Application entitled Selective Removal Of A Coating From A Metal Layer, And Solar Cell Applications Thereof) first to selectively ablate the nitride;
7) Underlying metal etching by immersing entire substrate in etchant, followed by dielectric coating removal by ultrasonic/rinse; and
8) Plate

Further, it is understood that such a process sequence is applicable to forming contact structures on the front and/or back surface of solar cells. Also, it is understood that the sequence may be implemented on both the front and back surfaces simultaneously without adding additional process steps.

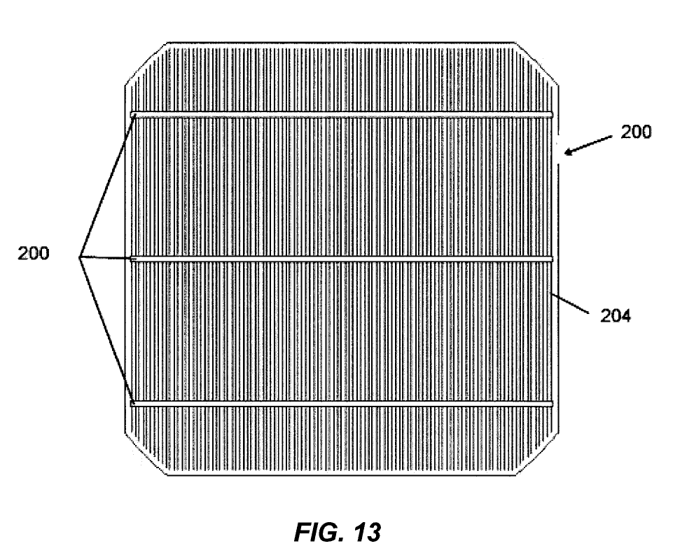

In another example, FIG. 13 shows a nominal metal pattern as it may appear on the front and/or back side of a solar cell substrate 200. A metal pattern may for example consist of bus-bars 200 and narrow line fingers 204.

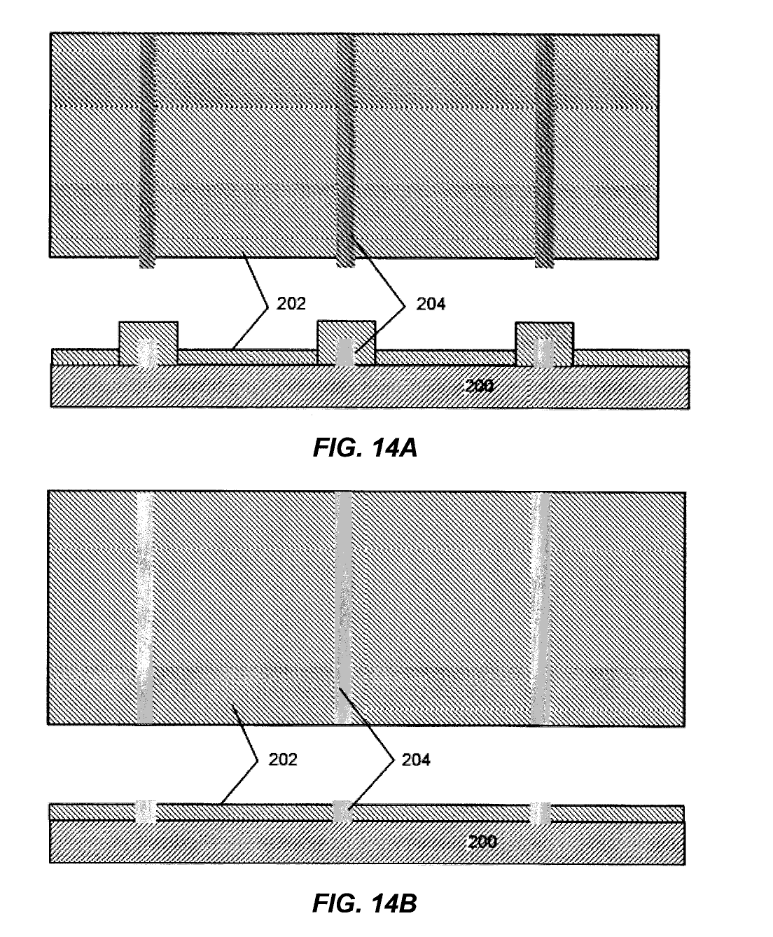

FIGS. 14A and 14B show close up details of narrow line metal fingers 204 as they may appear in a part of the solar cell. A dielectric coating 202 may cover metal fingers 204. FIG. 14A and FIG. 14B show before and after underlying metal etch and dielectric coating removal from on top of the metal fingers.

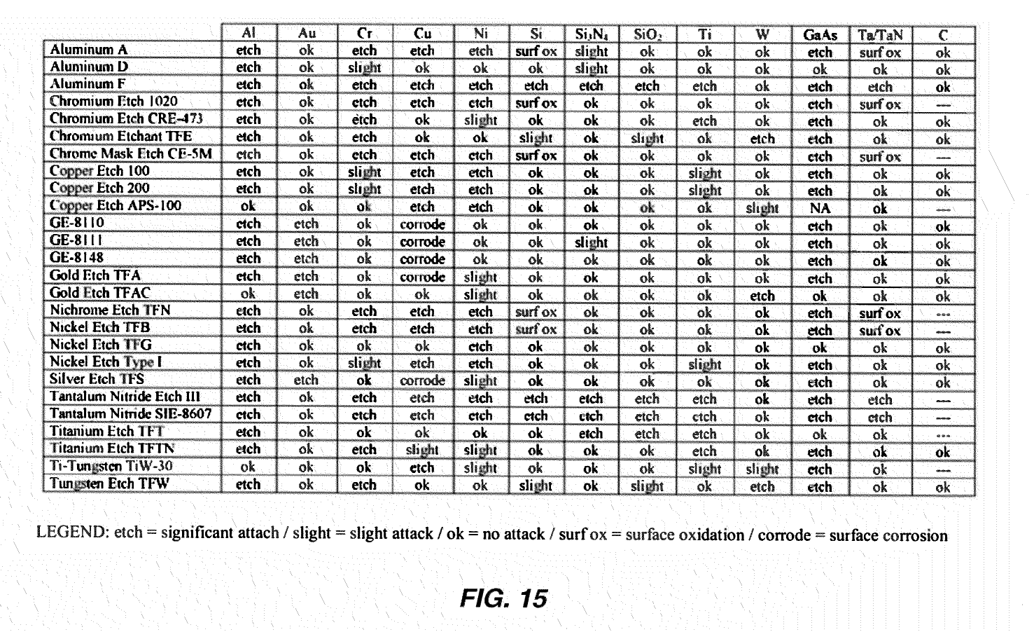

FIG. 15 is a table obtained from showing that different etchants can be formulated to selectively etch materials (Source: Transene Company Inc's website). The appropriate etchant (not limited to those listed in the table) can be selected or formulated based on what needs to be etched and what needs to remain unaffected. It also depends on the characteristics of materials that need to be etched (type, method of deposition, thickness, coverage, # of layers etc.), the characteristics of the top layer the etchant has to go through (i.e. type, porosity, strength, uniformity, elemental composition etc.), characteristics of layers that need to remain unaffected (material type, material quality, etc.), process time limitations, throughput requirements, cost etc.

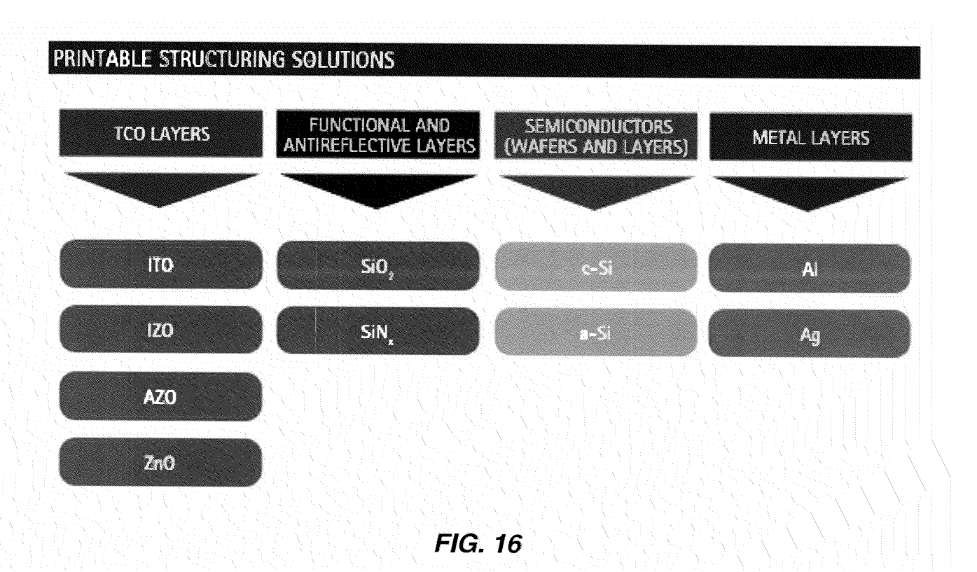

For selective coating and etching of patterned metal, etch pastes such as those from EMD isishape SolarEtch® product portfolio can be used. Companies such as EMD, Transene etc. have printable etch pastes that can be used to etch layers of nearly all types of transparent conductive oxides, (e.g. ITO, ZnO), antireflective layers or diffusion barriers (e.g. SiO2, SiNx), semiconductors (e.g. a-Si, poly-Si) and metals (e.g. aluminum). The types of materials that may be etched by such products are illustrated in FIG. 16.

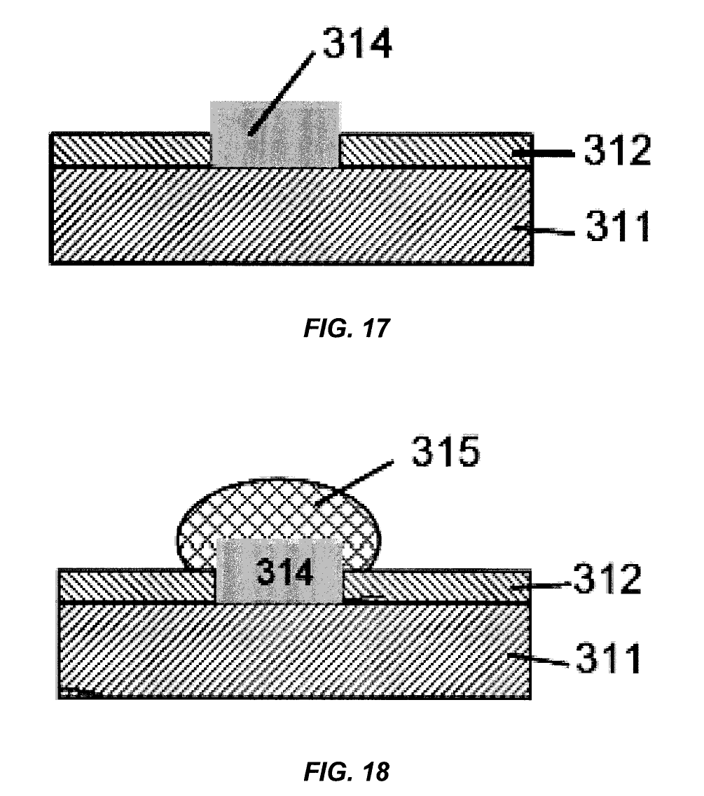

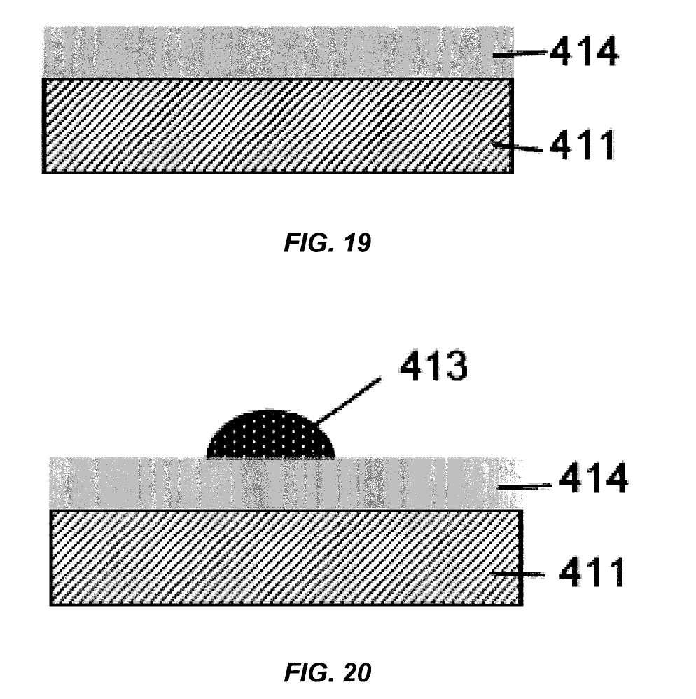

In another example, an improved structure for a front side metallization is sketched in FIG. 17. The line width of the metallization line 14 is on the order of 50 μm or less and the total surface coverage with metal of the front side is about 7% or less. As depicted in FIG. 17, a thin metal contact 314 may subsequently be plated to result in a plate metal contact 315 at required thickness in order to obtain a higher conductivity. Using electroplating for the buildup of the line conductivity, a sufficient thickness of the metal contact 314 on the order of ˜50-500 nm is required in order to enable good plated metal contact 315 uniformity. It is understood that when plating is performed, an antireflection coating 312 must also function as a plating barrier to prevent metal plating onto the surface of the substrate, for this reason alone the antireflection coating must be a good electrical insulator (e.g. a largely intact dielectric film).

In one example, the invention includes a method to manufacture conductive metal grids on substrates, for example solar cells, by employing selective laser ablation of a dielectric coating from a metal pattern.

In one embodiment, a resist is used to locally etch back a metal layer followed by the deposition of a dielectric coating on a full area including the metalized area, and the selective laser ablation of the dielectric coating from on top of the metal.

In a further embodiment, inkjet or aerosol printing of metal nanoparticles may be used to form a metal pattern which is followed by the deposition of a dielectric coating on a full area including the metalized area, and the selective laser ablation of said dielectric coating from on top of the metal.

In another embodiment, screen printing of metal paste is used to form a metal pattern which is followed by the deposition of a dielectric coating on the full area including the metalized area, and the selective laser ablation of said dielectric coating from on top of the metal.

The present invention offers many distinct advantages over current state of the art. Specifically, it is a simple technique for the formation of a metal pattern surrounded by an dielectric coating for solar cells, where said dielectric coating may function as an antireflection coating on the front surface, internal reflector on the rear surface and may further may function as a dielectric barrier for subsequent electroplating of metal patterns on either surface. Also, this is a favorable way of fabricating interdigitated contact grids for contact structures that are made on one side of the substrate only.

In one embodiment of the present invention very fine metal patterns may be generated, as a dielectric coating is selectively removed by laser ablation only from those substrate areas covered with patterned metal even though a larger area of the substrate is irradiated by a laser beam. This selective laser ablation of a dielectric coating is a self-aligned patterning processes as it relies on an interaction between the laser irradiation, metal contact and the overlying portion of dielectric coating for the removal of the dielectric coating. Dielectric coating and the substrate in those areas not covered by metal is largely unaffected by the laser irradiation, even though these areas may be irradiated by the same laser beam. This self-aligned laser ablation of the dielectric coating means that very narrow metal patterns may be generated, the size of the dielectric coating opening only being governed by the metal pattern size and the wavelength of the laser irradiation. Furthermore, such a self-aligned selective laser ablation patterning is a simple, high yield and cost effective manufacturing process.

The selective laser ablation patterning of the dielectric coating avoids any gap between the metal and the dielectric antireflection coating as otherwise can be observed in techniques such as metal lift-off This is important because the dielectric coating acts as a barrier between the substrate and any plated metal and the surrounding environment.

FIGS. 19-32 show an example embodiment of the invention which uses a metal etch resist to form a metal grid pattern for a solar cell. It is understood that many techniques exist for the formation of a metal patterns on a substrate and that the sequence presented is only one possible example.

A substrate 411 is supplied. This substrate may be a silicon semiconductor wafer of either p or n-type doping. The substrate may be textured, for example with a random pyramid pattern to improve light trapping in the solar cell. The substrate may have dopant diffusions on either or both sides to form emitter structures or surface fields. Such dopant diffusions may be patterned, for example to form so called selective emitter structures. The substrate may have thin film passivation layers present on either or both surfaces. Such passivation layers may for example consist of doped or intrinsic amorphous silicon layers, silicon dioxide, silicon nitride, doped or intrinsic poly-silicon, doped or intrinsic silicon carbide, aluminum oxide or any of a large variety of such passivation layers and combinations thereof.

A metal film may be deposited onto a surface of substrate 411, and the structure shown in FIG. 19 results. Such metal deposition may, for example, be performed using well established techniques such as sputtering, thermal evaporation or e-beam evaporation. It is understood that this metal film may consist of multiple different metal layers where these metal layers are required to perform different functions. For example, a bottom (next to the substrate) metal layer maybe required to form good electrical contact and adhesion to the substrate, a top or middle metal layer may be required to act as a diffusion barrier and a top metal layer may need to function as an electroplating seed. Further, it is understood that the metal film may require specific properties, for example thickness and/or composition, to enable a subsequent selective dielectric laser ablation.

A narrow resist 413 (e.g., a resist line) may be dispensed on top of metal film 414, and the structure shown in FIG. 20 results. Resist 413 may form any pattern on the surface of the substrate. In the case of a solar cell such a pattern may, for example, consist of many narrow fingers and several wider bus-bars. Resist 413 may be dispensed, for example, by inkjet or screen printing. Alternatively, resist 413 (e.g., a narrow resist line) could be formed by photolithographic means.

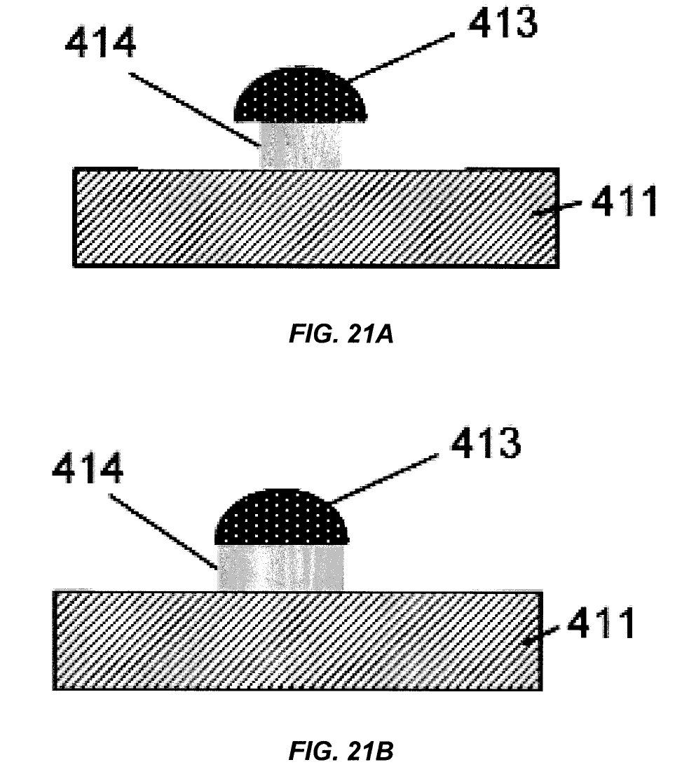

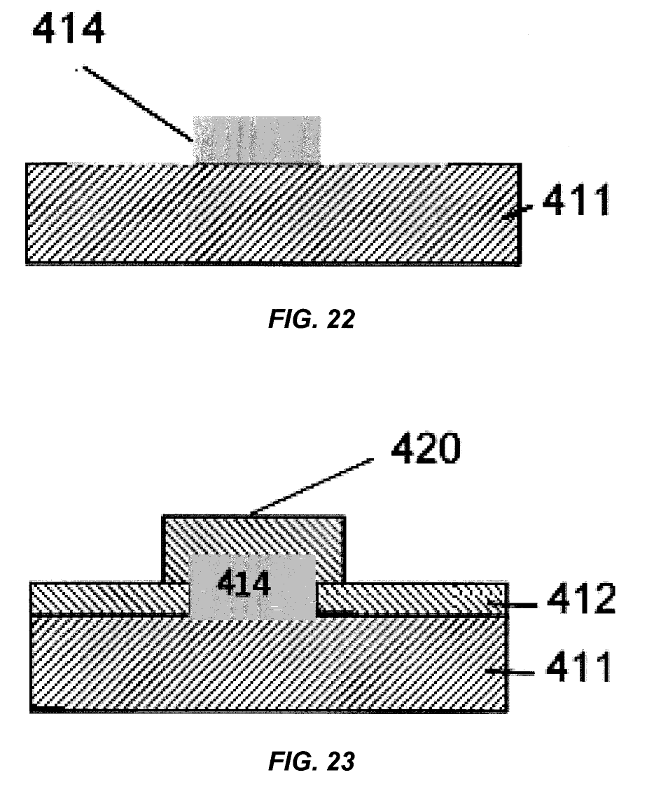

Metal film 414 may be etched except for the parts covered by resist 413, and the structure shown in FIG. 21 results. Metal etching may, for example, be performed by acid etching. The degree of metal etching may be controlled to create a large or small or no undercut thus defining a final line width.

The resist (e.g., resist 413) may be removed and a metal pattern left on the substrate, the structure shown in FIG. 22 results. In the case of a front surface of solar cell, finger widths of less than 50 μm may readily be achieved.

A dielectric coating 412 may be deposited across an entire surface (e.g., over substrate 411 and metal film 414), and the structure shown in FIG. 23 results. Such dielectric deposition may, for example, be performed using well established techniques such as sputtering, dip coating, chemical vapor deposition and plasma enhanced chemical vapor deposition. In the case of the front surface of a solar cell it is understood that dielectric coating 412 may function as an antireflection coating and may also passivate the surface of the solar cell. Further, it is understood that dielectric layer 414 may be composed of multiple different layers and/or graded layers, to for example implement well known techniques to improve antireflection properties.

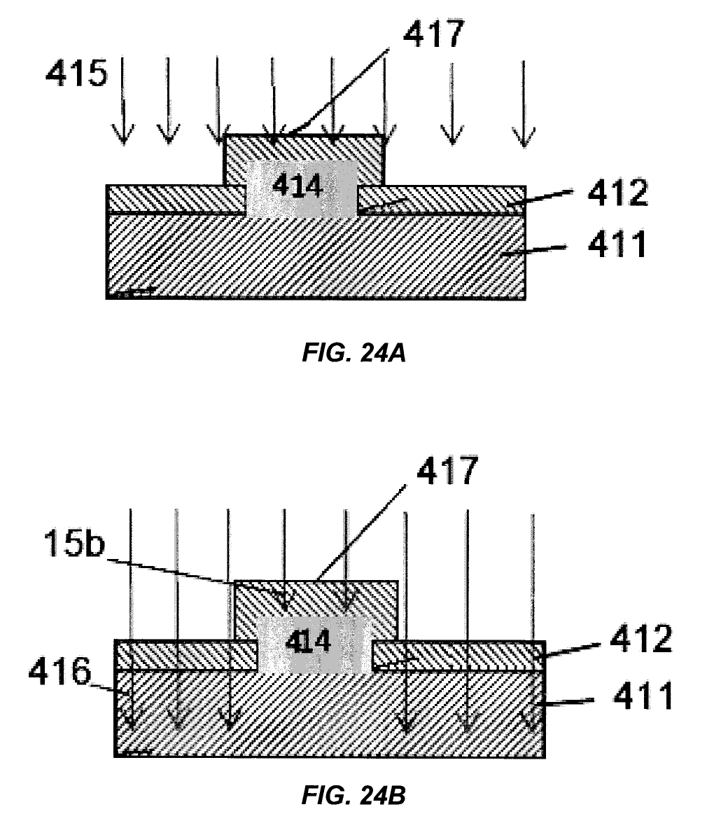

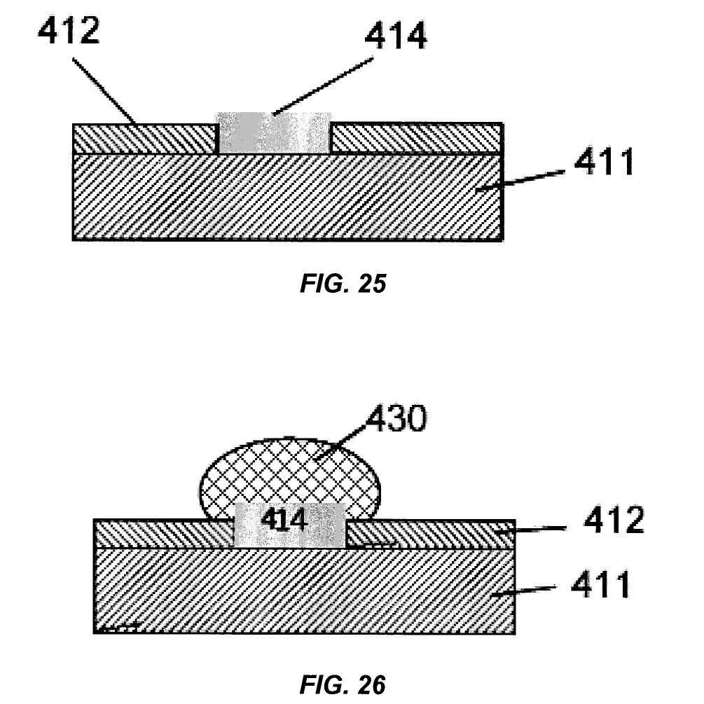

The surface of the substrate may be irradiated with a laser beam 415, as shown in FIG. 24. The entire surface of the substrate structure (e.g., substrate 411, coating 412, and metal film 414) may be irradiated or alternatively only those areas which have a metal pattern may be irradiated. As a result of this selective dielectric ablation the structure shown in FIG. 25 results. As depicted after the removal of the dielectic layer metal contact 414 and the dielectric layer cover the entire substrate 411 without any gap between metal contact 414 and dielectric coating 412

In one embodiment, the laser irradiation parameters are chosen such that neither dielectric coating 412 nor substrate 411 significantly interact with the beam, the laser beam passing through as depicted by arrow 416 these without causing significant damage. The laser irradiation parameters are chosen to significantly interact with metal film 414, and the laser beam is absorbed in metal film 414. This absorption can result in the partial ablation of the metal film, specifically a thin layer at the surface of the metal may be ablated. This interaction leads to the local removal of the dielectric coating overlying the metal film 414 at portion 417.

Subsequent processes may be performed on the substrate, for example cleaning to remove debris or thermal treatment to improve electrical contact. In the case of the front surface of a silicon solar cell the metal film 14 may be thickened by plating to result in a plated contact 430, as shown in FIG. 26, to achieve the required line conductivity. Dielectric coating 412 serves as a barrier between the plated metal 430 and substrate 411.

Taken together, the above described example illustrates a simple process sequence for the formation of metal contact structures for solar cells. The process sequence is as follows in one example:
1) Deposit metal film on substrate;
2) Dispense resist;
3) Etch metal and remove resist;
4) Deposit dielectric film;
5) Laser Ablate; and
6) Plate

Further, it is understood that such a process sequence is applicable to forming contact structures on the front and/or back surface of solar cells. Further, it is understood that the sequence may be implemented on both the front and back surfaces simultaneously without adding additional process steps.

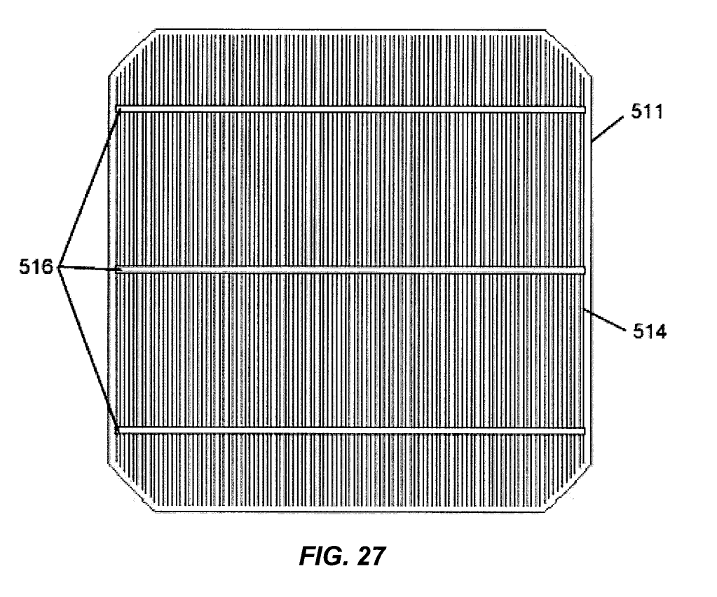

In another example, FIG. 27 shows a nominal metal pattern as it may appear on the front and/or back side of a solar cell substrate 511. The metal pattern may for example consist of bus-bars 516 and narrow line fingers 514.

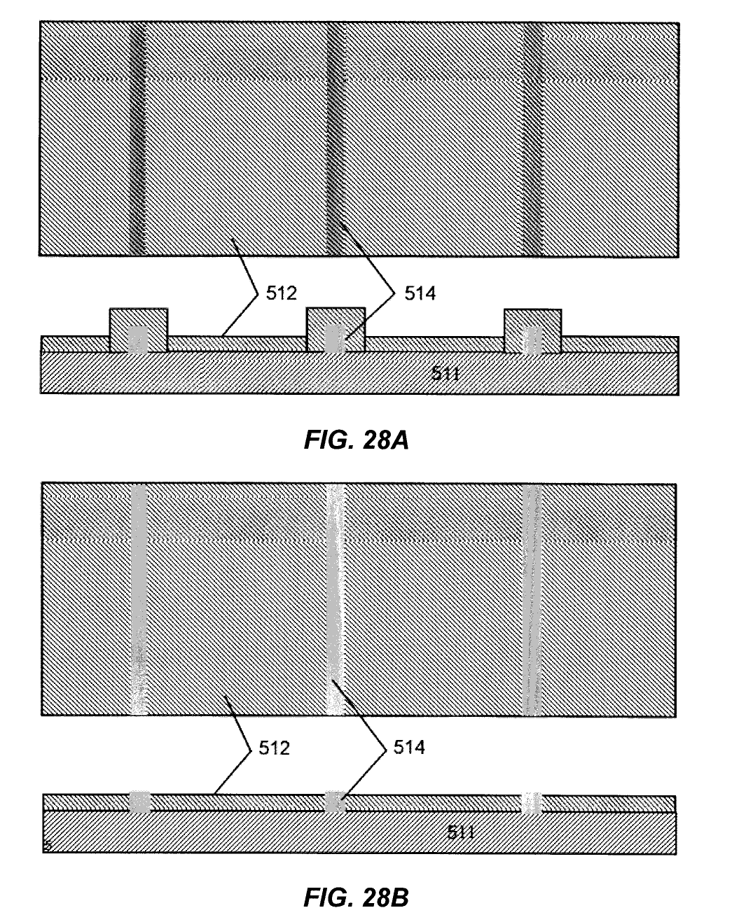

FIGS. 28A and 28B show close up details of narrow line metal fingers 514 as they may appear in a part of the solar cell. FIG. 27A in plane view and section view shows a dielectric coating 502 covering the metal fingers 514. FIG. 28b shows after laser irradiation has removed the dielectric coating from on top of the metal fingers.

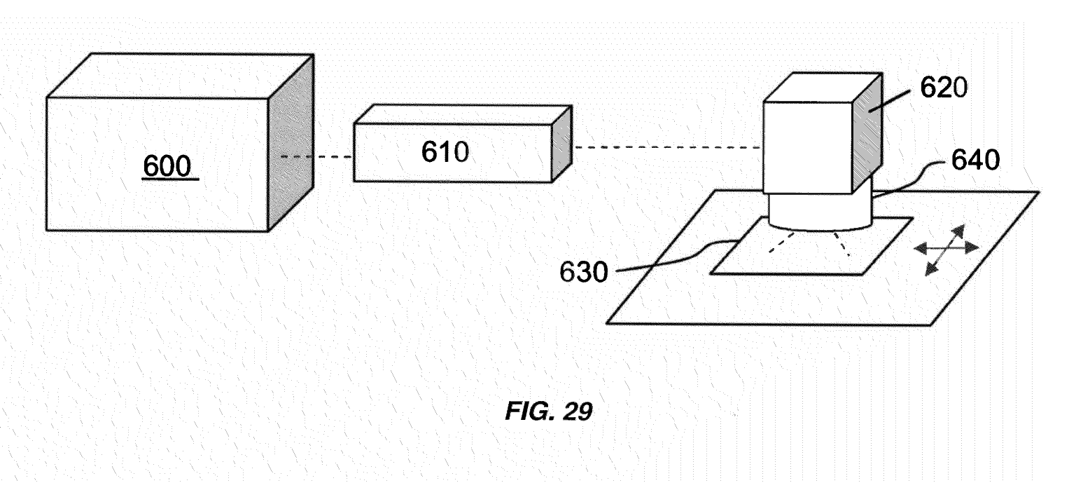

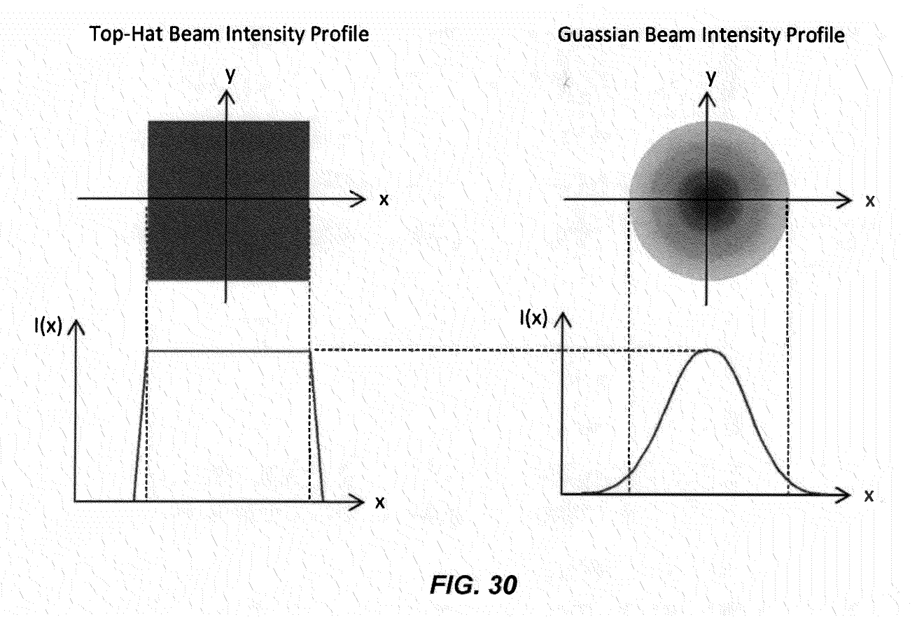

FIG. 29 shows a simplified diagram of a laser machining system suitable for performing the laser processing as described in this patent application. A laser beam is generated in a laser 600. The laser beam is fed through optional external optics 610 which may include components such as a beam expander, beam collimator, beam homogenizer, imaged mask, fiber beam delivery system, variable attenuator, relay lenses and mirrors. A galvanometer scanner 620 and/or a translation stage is used translate the laser beam to cover a substrate (e.g., a solar cell 630). A final lens is used to focus the beam onto the substrate (solar cell). Such a laser machining system arrangement, as illustrated in FIG. 29, is readily available and applicable to high throughput industrial applications such as solar cell manufacturing.

This invention may use different laser beam intensity profiles. FIG. 30 shows an example of two applicable beam profiles. A Gaussian beam profile (or close to Gaussian) is one typically generated by many laser sources, the intensity distribution in any transverse plane is a circularly symmetric Gaussian function centered about the beam axis. An alternative beam profile shown is the so called “Top-Hat” or “Flat-Top” beam profile. Such a profile ideally has a near-uniform intensity within the exposure area. The Top-Hat exposure area shape may be circular, square, rectangular or any shape generated by appropriate optics. Such a Top-Hat beam profile is typically generated using special diffractive or refractive optics (or multimode fibers) called beam shapers. Either of these profiles or combinations or variations thereof may be used for laser processing in this invention.

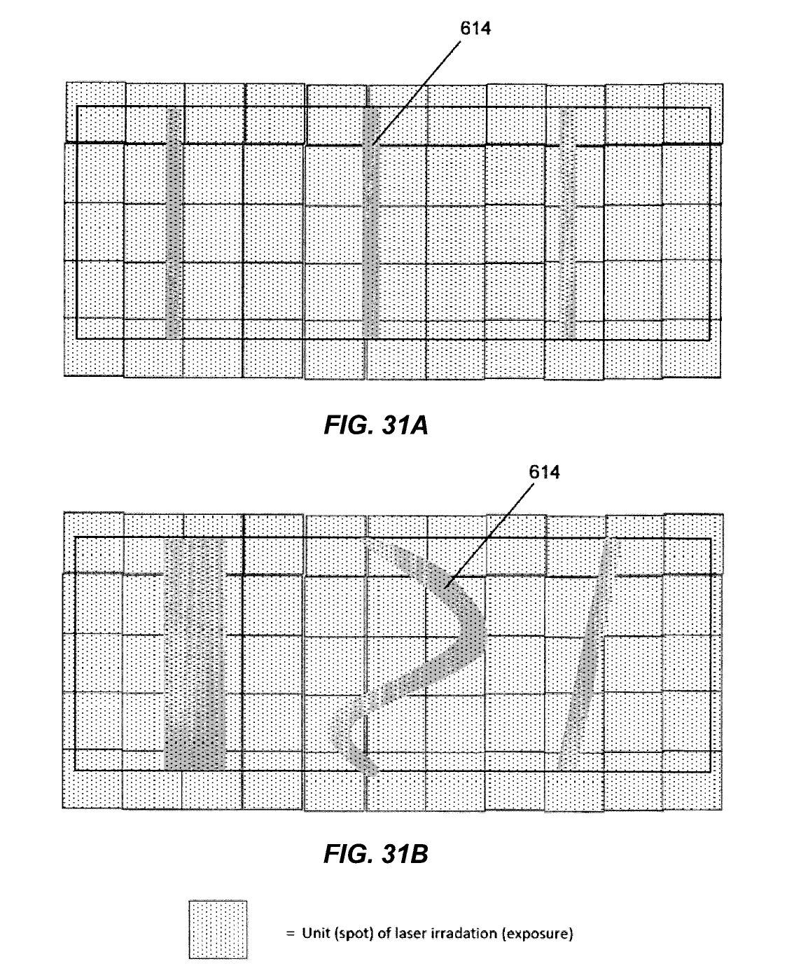

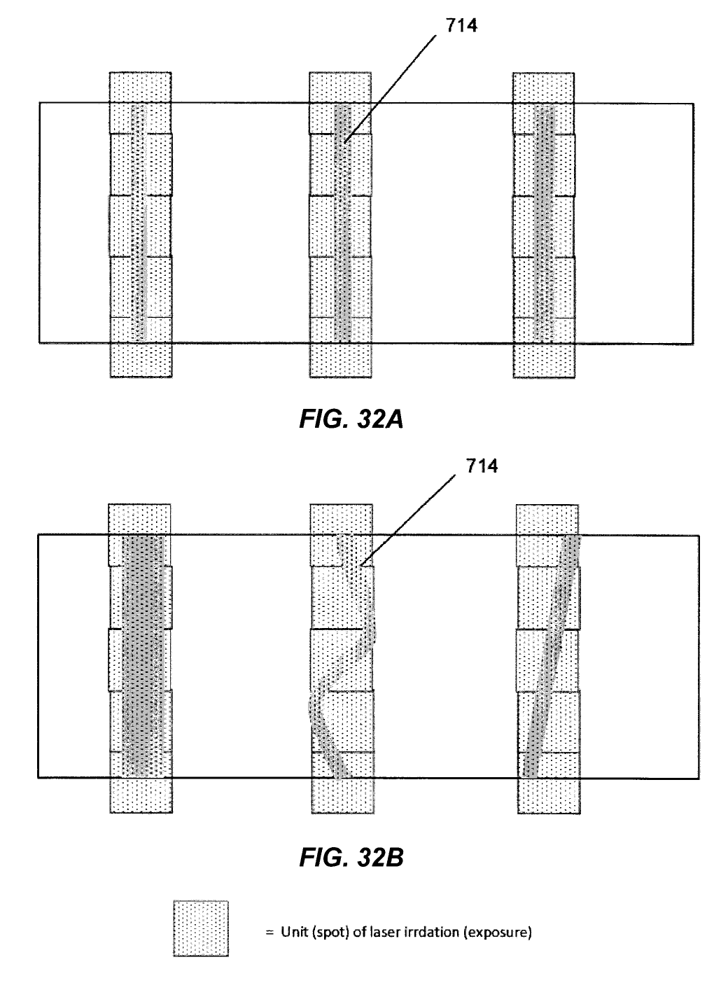

FIGS. 31A, 31B, 32A, and 32B show examples of how a square top-hat beam profile may be scanned or translated over a substrate, in a process for the self-aligned selective laser ablation of a dielectric coating overlying a patterned metal film 614 and a pattern metal film 714. As can be seen, this process is tolerant to variations in the size, placement and shape of the narrow metal fingers (e.g., of metal film 614). It is understood that a variety of different beam scanning, overlap and placement schemes are applicable to this invention and that the two shown are only representative examples of the general principle.

For example, a square spot of laser irradiation may be scanned or translated to cover an entire process area as depicted in FIG. 31A. As can be seen from FIG. 31B, for a self-aligned selective laser ablation process removing a dielectric coating overlying patterned metal film 614, this irradiation pattern functions irrespective of the size, position or shape of patterned metal film 614.

In another example depicted in FIG. 32A, a square top-hat profile laser beam spot may be scanned or translated to cover narrow metal film fingers 714. As can be seen from FIG. 32B, for a selective laser ablation process removing a dielectric coating overlying a patterned metal film 714, this irradiation pattern does not need to accurately track variations in the size, position or shape of narrow metal lines of film 714.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

What is claimed is:

1. A method for patterning a film pattern on a substrate comprising:
forming a film pattern on a substrate surface;
forming a coating over the substrate and the film pattern;
inducing porosity or openings in the coating; and
removing at least part of the coating overlying the film pattern including etching at least one layer underlying the coating ahead of removing at least part of the coating.

2. The method of claim 1 where the film pattern is formed by:
forming a film, on a surface of the substrate;
forming an etch resist over the film;
etching the film in one or multiple steps including faster removal of a top layer of the at least one layer by etching an underlying layer of the at least one layer first; and
removal of the etch resist.

3. The method of claim 1 wherein the film pattern is formed by one of screen printing a metal paste, inkjet printing a nanoparticle metal ink and aerosol printing metal nanoparticles.

4. The method of claim 1 wherein the substrate and the coating avoid significantly interacting with etchants attacking the at least one layer.

5. The method of claim 1 wherein the etchant interacts with the film pattern and overlying coating leading to the partial or complete removal of the overlying coating, with the remaining overlying coating being unsupported.

6. A structure on a surface on a substrate wherein a film pattern is surrounded by a coating and where no gap exists between the pattern and the surrounding coating.

7. The method of claim 1 wherein the substrate is a photovoltaic device.

8. The method of claim 1 wherein the film pattern forms a front and/or a back contact electrode of a solar cell.

9. The method of claim 1 further comprising subsequently electroplating the film pattern with metal to improve electrical conductivity of the metal grid.

10. The method of claim 1 wherein the coating is a dielectric optical antireflection layer.

11. The method of claim 1 wherein the dielectric coating is an optical reflecting layer.

12. The method of claim 2 wherein the patterned resist is directly-written and in-situ cured with no need for subsequent pattern mask exposure and developing.

13. The method of claim 12 wherein the patterning resist direct-write technique is ink jetting or screen-printing.

14. The method of claim 1 wherein the metal film pattern comprises multiple thin film metal layers of different or varying composition and thicknesses.

15. The method of claim 14 wherein the multiple thin film metal layers comprise one or more of the following metals or metal alloys: chromium, silver, copper, nickel, titanium, aluminum, nickel-vanadium, nickel-niobium, nickel-titanium, nickel-zirconium, nickel-chromium, nickel-platinum, nickel-aluminum, nickel-tungsten, titanium-tungsten, cobalt-nickel, chromium-cobalt-nickel, chromium-cobalt, chromium-nickel, chromium-silicon, chromium-copper, chromium-aluminum, aluminum-silicon-copper, aluminum-silicon, and aluminum-chromium.

16. The method of claim 5 where the metal film comprises a top metal film in a stack of multiple thin film metals, the top metal film being directly electroplate-able and consists of one of the following metal layers: silver, copper, nickel, chromium, nickel-niobium, nickel-vanadium, nickel-titanium, nickel-zirconium, nickel-chromium, nickel-platinum, nickel-aluminum, nickel-tungsten, chromium-cobalt-nickel, chromium-cobalt, chromium-nickel, chromium-silicon, chromium-copper and chromium-aluminum.

17. The method of claim 1 wherein the etching comprises the entire substrate being immersed in an etchant or the etchant being applied selectively to match the underlying film pattern; wherein the etchant passes through pinholes or openings in a top layer that is already present or introduced prior to this step by one of chemical, physical, electrical, and topographical methods.

18. The method of claim 1 wherein the substrate comprises a silicon wafer solar cell, one or both surfaces of which are textured to improve light trapping.

19. The method of claim 1 wherein the etching partially removes or disrupts the dielectric coating overlying the film pattern.

20. The method of claim 1 wherein the film pattern comprises a metal.
